(19) United States
(12) Patent Application Publication
(10) Pub. No.: US 2025/0155814 A1
(43) Pub. Date: May 15, 2025

(54) SPIN COATING APPARATUS

(71) Applicant: Samsung Electronics Co., Ltd., Suwon-si (KR)

(72) Inventors: Chulmin Cho, Suwon-si (KR); Youngho Hwang, Suwon-si (KR); Juno Park, Suwon-si (KR); Kyoungwhan Oh, Suwon-si (KR); Sunyoung Yun, Suwon-si (KR); Youngkyun Im, Suwon-si (KR); Jaehong Lim, Suwon-si (KR); Seok Heo, Suwon-si (KR)

(21) Appl. No.: 18/751,464

(22) Filed: Jun. 24, 2024

(30) Foreign Application Priority Data
Nov. 10, 2023 (KR) 10-2023-0155663

(51) Int. Cl. G03F 7/16; B05C 11/08

(52) U.S. Cl. CPC G03F 7/162; B05C 11/08

(57) ABSTRACT

A spin coating apparatus according to an embodiment includes a substrate supporter supporting a substrate, a substrate supporter driver rotating the substrate supporter, a laser supply unit disposed on the substrate supporter and providing a laser, and a laser driver of driving the laser supply unit, wherein the laser supply unit may move along a first direction, which is horizontal to the substrate surface on the substrate supporter.

### CROSS-REFERENCE TO RELATED APPLICATION

This application claims priority to and the benefit of Korean Patent Application No. 10-2023-0155663 filed in the Korean Intellectual Property Office on Nov. 10, 2023, the entire contents of which are incorporated herein by reference.

### BACKGROUND

The present disclosure relates to a spin coating apparatus and a spin coating method.

A spin coating method is used to laminate a photoresist film on a substrate, which is essential for a photolithography process.

The spin coating method spreads a photoresist solution on the substrate by using a centrifugal force caused by a rotation of a substrate supporter, and the thickness of the photoresist solution is controlled the rotation speed of the substrate supporter.

However, if the rotation speed of the substrate supporter is slow, the photoresist solution cannot spread widely, and if the rotation speed is fast, the thickness of the photoresist solution may be thicker at the outer part of the substrate than at the center of the substrate.

Thickness errors in the photoresist film may lead to errors in the photolithography process.

### SUMMARY

The embodiments are intended to provide a spin coating apparatus and a spin coating method that may deposit a coating material of uniform thickness over a large area of a substrate without increasing a use amount of the coating material.

However, tasks to be solved by embodiments may not be limited to the above-described task, and may be extended in various ways within a range of technical scopes included in the present disclosure.

Embodiments are directed to a spin coating apparatus. The spin coating apparatus includes a substrate supporter configured to support a substrate, a substrate supporter driver configured to rotate the substrate supporter, a laser supply unit positioned above the substrate supporter and configured to supply a laser, and a laser driver configured to drive the laser supply unit. The laser supply unit is configured to move along a first direction, the first direction being horizontal relative to a surface of the substrate when supported on the substrate supporter.

Further embodiments are directed to a spin coating method. The spin coating method includes mounting a substrate on a substrate supporter, supplying a coating material on the substrate, rotating the substrate supporter in a rotation direction, supplying a laser to the coating material from a laser supply unit, and moving the laser supply unit above the substrate supporter along a first direction, the first direction being horizontal relative to a surface of the substrate.

Further embodiments are directed to a method for spin coating a coating material on a substrate. The substrate includes a first region adjacent to a center of the substrate, a second region spaced apart from the first region toward an edge of the substrate along a first direction, and a third region adjacent to the edge of the substrate. The first direction is horizontal relative to a surface of the substrate. The method includes mounting the substrate on a substrate supporter; supplying the coating material on the substrate; rotating the substrate supporter in a rotation direction; supplying a laser to the substrate from a laser supply unit located above the substrate supporter, moving the laser supply unit along the first direction at a first moving speed and supplying the laser at a first intensity when at a position corresponding to the first region of the substrate; moving the laser supply unit along the first direction at a second moving speed and supplying the laser at a second intensity when at a position corresponding to the second region of the substrate; and moving the laser supply unit along the first direction at a third moving speed and supplying the laser at a third intensity when at a position corresponding to the third region of the substrate.

According to embodiments, the spin coating apparatus and the spin coating method that may stack the coating material of the uniform thickness over the large area without increasing the amount of the coating material used.

The effects of embodiments are not limited to the above-described effects, and may be expanded in various ways in the range of the ideas and the areas of the present disclosure.

### BRIEF DESCRIPTION OF THE DRAWINGS

FIG. 1 is a simplified diagram of a spin coating apparatus according to embodiments.

FIG. 2 and FIG. 3 are top plan views of a part of the spin coating apparatus of FIG. 1.

FIG. 4 is a flowchart showing a spin coating method according to embodiments.

FIG. 5 is a graph showing a result of an experimental example according to embodiments.

FIG. 6 is a schematic view showing a result of an experimental example according to embodiments.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of the present disclosure.

In order to clarify the embodiments, parts that are not connected with the description will be omitted, and the same elements or equivalents are referred to by the same reference numerals throughout the specification.

Further, the accompanying drawings are provided only in order to allow embodiments disclosed in the present specification to be easily understood, and are not to be interpreted as limiting the spirit disclosed in the present specification, and it is to be understood that the embodiments include all modifications, equivalents, and substitutions without departing from the scope and spirit of this disclosure.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or above the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

In addition, in the specification, when referring to “connected to”, this does not only mean that two or more constituent elements are directly connected, but also that two or more constituent elements are electrically connected through other constituent elements as well as being indirectly connected and being physically connected, or it may mean that they are referred to by different names according to a position or function, but are integrated.

Below, various embodiments and variations of the present invention are described in detail with reference to accompanying drawings.

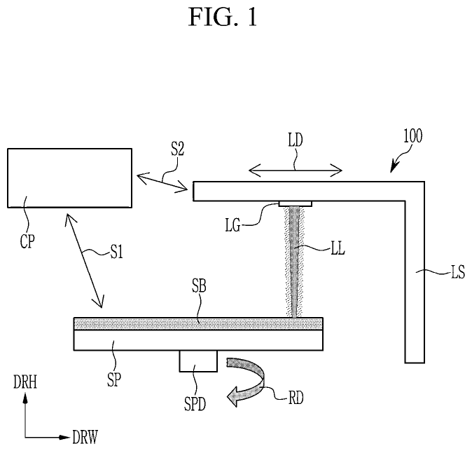

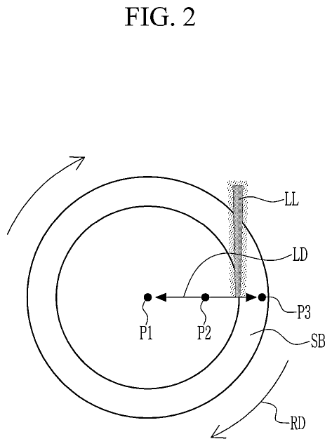

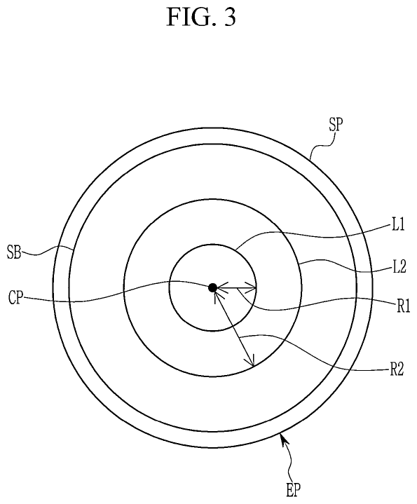

A spin coating apparatus 100 according to embodiments of the present invention is described with reference to FIG. 1 to FIG. 3. FIG. 1 is a simplified diagram of a spin coating apparatus according to embodiments of the present invention. FIG. 2 and FIG. 3 are top plan views of a part of the spin coating apparatus of FIG. 1.

Referring to FIG. 1, the spin coating apparatus 100 of the present invention may include a substrate supporter SP to which a substrate SB may be mounted, a substrate supporter driver SPD for driving (e.g., moving and rotating) the substrate supporter SP, a laser supply unit LG for providing a laser LL, a laser driver LS, and a main driver CPD. Although not shown, the spin coating apparatus 100 according to embodiments of the present invention may further include a coating material supply unit that supplies a necessary coating solution onto the substrate SB.

The substrate supporter SP may support the mounted substrate SB. The substrate supporter SP may be moved in an up/down direction DRH perpendicular to a surface of the substrate supporter SP in order to attach or detach the substrate SB. For example, the substrate supporter SP may move upward and be in contact with the substrate SB, thereby supporting the substrate SB, and the substrate supporter SP may move downward, thereby detaching the substrate SB from the substrate supporter SP. The substrate SB may be mounted and detached to the process space by known methods such as a robot arm.

The substrate supporter driver SPD may rotate the substrate supporter SP in a rotation direction RD. As the substrate supporter SP rotates, the substrate SB mounted on the substrate supporter SP may also be rotated in the rotation direction RD. The rotation direction RD is shown as a clockwise direction, but embodiments of the present invention are not limited thereto, and the rotation direction RD may be a counterclockwise direction or both a clockwise and counterclockwise direction.

The laser supply unit LG may be provided for supplying the laser LL. The laser supply unit LG may be disposed on or positioned above the substrate supporter SP and supply the laser LL on the substrate SB mounted on the substrate supporter SP. The laser supply unit LG is mounted on the laser driver LS and may move along the movement direction LD which is parallel relative to a horizontal direction DRW. The laser driver LS may support the laser supply unit LG and control the moving speed of the laser supply unit LG and the intensity of the laser LL supplied from the laser supply unit LG.

The laser LL supplied through the laser supply unit LG may be a laser in the infrared region.

The main driver CPD may drive the substrate support driver SPD and the laser driver LS. For example, the main driver CPD may transmit and receive a first signal S1 with the substrate supporter driver SPD and control the up/down movement and the rotational movement of the substrate supporter SP. The main driver CPD may also transmit and receive a second signal S2 with the laser driver LS and control the moving speed of the laser supply unit LG and the intensity of the laser LL supplied from the laser supply unit LG.

Although not shown, the spin coating apparatus 100 according to embodiments of the present invention may further include an observation unit for observing the coating material coated on the substrate SB. For example, the observation unit may include a camera, but embodiments of the present invention are not limited thereto.

Referring to FIG. 2 along with FIG. 1, as the substrate supporter SP rotates in the rotation direction RD, the substrate SB mounted on the substrate supporter SP may also rotate in the rotation direction RD.

The laser supply unit LG may move along the movement direction LD by the laser driver LS. The laser supply unit LG may move horizontally through a first portion P1 corresponding to a central portion of the substrate SB, a second portion P2 of the substrate SB which is spaced apart from the first portion P1, and a third portion P3 corresponding to a region adjacent to an edge of the substrate SB.

The first portion P1, the second portion P2, and the third portion P3 of the substrate SB may be arranged in a line along the movement direction LD that is parallel relative to the horizontal direction DRW.

The moving speed of the laser supply unit LG may be different, and the intensity of the laser LL supplied from the laser supply unit LG may also be different at positions corresponding to the first portion P1, the second portion P2, and the third portion P3 of the substrate SB. The moving speed of the laser supply unit LG and the intensity of the laser LL may be controlled by the laser driver LS.

According to some embodiments of the present invention, a first moving speed of the laser supply unit LG in the first portion P1 of the substrate SB may be greater than a second moving speed of the laser supply unit LG in the second portion P2 of the substrate SB, and the second moving speed of the laser supply unit LG in the second portion P2 of the substrate SB may be greater than a third moving speed of the laser supply unit LG in the third portion P3 of the substrate SB.

A first intensity of the laser LL supplied from the laser supply unit LG in the first portion P1 of the substrate SB may be substantially the same as a second intensity of the laser LL supplied from the laser supply unit LG in the second portion P2 of the substrate SB, and the second intensity of the laser LL supplied from the laser supply unit LG in the second portion P2 of the substrate SB may be substantially the same as a third intensity of the laser LL supplied from the laser supply unit LG in the third portion P3 of the substrate SB.

According to some embodiments of the present invention, the second intensity of the laser LL supplied from the laser supply unit LG in the second portion P2 of the substrate SB may be greater than the first intensity of the laser LL supplied from the laser supply unit LG in the first portion P1 of the substrate SB, and the third intensity of the laser LL supplied from the laser supply unit LG in the third portion P3 of the substrate SB may be greater than the second intensity of the laser LL supplied from the laser supply unit LG in the second portion P2 of the substrate SB.

The first moving speed of the laser supply unit LG in the first portion P1 of the substrate SB may be substantially equal to the second moving speed of the laser supply unit LG in the second portion P2 of the substrate SB, and the second moving speed of the laser supply unit LG in the second portion P2 of the substrate SB may be substantially the same as the third moving speed of the laser supply unit LG in the third portion P3 of the substrate SB.

According to some embodiments of the present invention, the first moving speed of the laser supply unit LG in the first portion P1 of the substrate SB may be greater than the second moving speed of the laser supply unit LG in the second portion P2 of the substrate SB, and the second moving speed of the laser supply unit LG in the second portion P2 of the substrate SB may be greater than the third moving speed of the laser supply unit LG in the third portion P3 of the substrate SB.

The second intensity of the laser LL supplied from the laser supply unit LG in the second portion P2 of the substrate SB may be greater than the first intensity of the laser LL supplied from the laser supply unit LG in the first portion P1 of the substrate SB, and the third intensity of the laser LL supplied from the laser supply unit LG in the third portion P3 of the substrate SB may be greater than the second intensity of the laser LL supplied from the laser supply unit LG in the second portion P2 of the substrate SB.

Referring to FIG. 3 along with FIG. 1 and FIG. 2, in some embodiments, rotation of the substrate SB forms a first circumference length L1 of coating material on the substrate SB which is separated by a first radius R1 relative from a center CP of the substrate SB. In some embodiments, rotation of the substrate SB forms a second circumference length L2 of coating material on the substrate SB which is separated by a second radius R2 relative from the center CP of the substrate SB. In some embodiments, the second radius R2 is larger than the first radius R1 and the second circumference length L2 of coating material on the substrate SB is larger than the first circumference length L1 of coating material on the substrate SB.

As the corresponding coating material extends from the center CP of the substrate SB to an outer edge EP of the substrate supporter SP, the corresponding circumference length L1, L2 of the coating material on the substrate SB formed by the rotation of the substrate SB may increase.

As explained previously, when the substrate SB mounted on the substrate supporter SP rotates in the rotation direction RD by the rotation of the substrate supporter SP, the laser supply unit LG may supply the laser LL while moving along the movement direction LD.

If the laser supply unit LG moves at a constant speed along the movement direction LD and supplies the laser LL with a constant intensity, the total energy of the laser LL applied to the portion of the substrate SB having a shorter first circumference length L1 and spaced apart relative to the center CP by the first radius R1 may be greater than the total energy of the laser LL applied to the portion of the substrate SB having a longer second circumference length L2 and spaced apart relative to the center CP by the second radius R2.

However, according to embodiments of the present invention, as the spin coating apparatus 100 moves from the center CP of the substrate SB toward the edge EP of the substrate supporter SP, from the first portion P1 of the substrate SB toward the second portion P2 of the substrate SB, and/or from the second portion P2 of the substrate SB toward the third portion P3 of the substrate SB, the moving speed of the laser supply unit LG may gradually decrease, or the intensity of the supplied laser LL may gradually increase. In addition, as the spin coating apparatus 100 moves from the first portion P1 of the substrate SB to the second portion P2 of the substrate SB and from the second portion P2 of the substrate SB to the third portion P3 of the substrate SB, the moving speed of the laser supply unit LG may gradually decrease, and the intensity of the laser LL simultaneously supplied may gradually increase.

Therefore, the total energy of the laser LL applied to the substrate SB may increase as it moves from the center CP of the substrate SB to the outer edge EP of the substrate supporter SP.

According to embodiments of the present invention, by controlling the moving speed of the laser supply unit LG and the intensity of the laser LL supplied by the laser driver LS, a desired intensity of the laser LL may be supplied according to the relative position of the substrate SB.

According to embodiments of the present invention, supplying the desired intensity of the laser LL relative to the position of the substrate SB while rotating the substrate SB in the rotation direction RD helps to diffuse the coating material. Thus, the viscosity of the coating material on the substrate SB may be lowered by supplying the intensity of the laser LL to the desired position of the coating material on the substrate SB, thereby providing a thin and uniform thickness of coating material on the substrate SB. In addition, by supplying the laser LL to the coating material, Marangoni effect may be induced in the coating material, helping the coating material spread to an edge of substrate SB. Accordingly, it is possible to coat the coating material with the uniform thickness over a wide area while thinning the total thickness of the coating material without increasing the amount of the coating material used on the substrate SB.

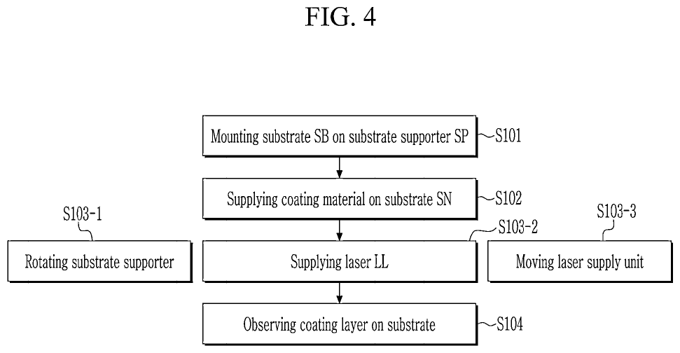

Next, a spin coating method S100 according to embodiments of the present invention will be described with reference to FIG. 4 along with FIG. 1 to FIG. 3. FIG. 4 is a flowchart showing a spin coating method according to embodiments of the present invention.

According to embodiments of the present invention, a substrate SB is mounted on a substrate supporter SP (block S101), and a coating material is supplied on the substrate SB (block S102).

The laser supply unit LG may be moved along the movement direction LD (block S103-3) while the substrate supporter SP (and the substrate SB with the coating material mounted on the substrate supporter SP) is rotated in the rotation direction RD (block S103-1), and the laser LL is supplied to the substrate SB from the laser supply unit LG (block S103-2).

By rotating the substrate supporter SP in the rotation direction RD, the substrate SB is also rotated in the rotation direction RD, and the coating material supplied on substrate SB may be diffused by a centrifugal force caused by the rotation.

At this time, the laser LL may be supplied to the coating material on the substrate SB. In some embodiments, the laser LL may be a laser in the infrared region. The laser LL supplied through the laser supply unit LG may penetrate through the coating material and be absorbed into the substrate SB. In some embodiments, the temperature of the substrate SB may be raised by the laser LL at a faster rate than when heated with a superheating device such as an electric heater. As the temperature of the surface of the substrate SB rises, the resultant heat energy may be transferred to the coating material supplied on the substrate SB.

When the heat energy is transferred to the coating material on the substrate SB, the viscosity of the coating material decreases, and the coating material may be diffused more easily and spread thinly on the substrate SB. In addition, when the heat energy is transferred to the coating material on the substrate, evaporation of a solvent of the coating material may be accelerated, but by controlling the intensity of the laser LL, the temperature of the coating material may be changed to achieve the desired degree of the diffusion of the coating material.

In order to reduce the thickness of the coating material on the substrate SB, the rotation speed of the substrate SB in the rotation direction RD may be increased. However, in this case, the thickness of the coating material at the edge of the substrate SB may become thicker. Additionally, if the amount of the coating material on the substrate SB is reduced, it may be difficult for the coating material to diffuse to the edge of the substrate SB.

However, according to embodiments of the present invention, by irradiating the laser LL to the coating material on the substrate SB, the viscosity of the coating material may be lowered, and thus the coating material may be easily spread to allow a thin and uniform thickness of the coating material to be provided on the substrate SB. Particularly, by reducing the speed of the laser supply unit LG or increasing the intensity of the laser LL as it moves toward the edge of the substrate SB, the energy of the laser LL may be increased, and accordingly, the coating material may be prevented from being thicker at the edge of the substrate SB. Thus, the coating material may be formed with a thin and uniform thickness at the edge of the substrate SB.

In addition, by irradiating the laser LL to the coating material on the substrate SB along the horizontal movement direction LD from the center CP of substrate SB to the edge, the Marangoni effect by heat energy may be induced in the coating material, and this may help the coating material diffuse easily in the circumferential direction corresponding to the edge side of the substrate SB, thereby coating the coating material having the thin thickness along the edge of the substrate SB. Therefore, the amount of the coating material used for coating the substrate SB may be reduced, and manufacturing costs may be reduced.

While supplying the laser LL from the laser supply unit LG to the substrate SB (block S103-2), when moving the laser supply unit LG along the movement direction LD (block S103-3), as the laser LL gradually moves from the center CP of the substrate SB to the edge EP of the substrate supporter SP, the moving speed of the laser supply unit LG may gradually decrease or the intensity of the supplied laser LL may gradually increase. In some embodiments, the moving speed of the laser supply unit LG may gradually decrease, and the intensity of the laser LL simultaneously supplied may gradually increase.

As the laser LL gradually moves from the center CP of the substrate SB to the edge EP of the substrate supporter SP, the total energy of the laser LL applied to each portion of the substrate SB may be substantially the same, or as the laser LL moves toward the edge EP of the substrate supporter SP, the total energy of the laser LL applied to the portion of the substrate SB may be increase.

Therefore, by diffusing the coating material on the substrate SB by the rotation of the substrate SB and simultaneously controlling the viscosity of the coating material by the intensity of the laser LL or inducing the flow of the coating material according to the Marangoni effect due to the laser LL, the coating material may diffuse to the edge of the substrate SB, thereby providing a thin and uniform thickness of the coating material on the substrate SB.

According to embodiments of the present invention, the coating material on the substrate SB may be observed (block S104) while the laser LL is being applied. Accordingly, the rotation speed may be controlled when rotating the substrate supporter SP (block S103-1), the intensity of the laser LL may be controlled when supplying the laser LL (block S103-2), and/or the moving speed of the laser supply unit LG may be controlled when moving the laser supply unit LG (block S103-3), thereby controlling the thickness of the coating material of the respective portions on the substrate SB.

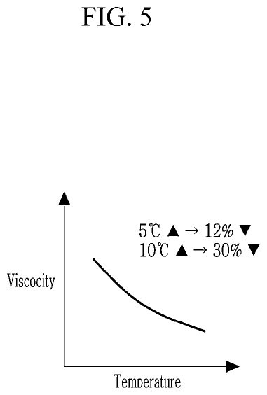

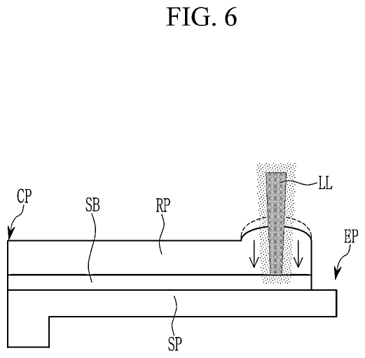

Next, an experimental example according to embodiments of the present invention is described with reference to FIG. 5 and FIG. 6. FIG. 5 is a graph showing a result of an experimental example according to embodiments of the present invention. FIG. 6 is a schematic view showing a result of an experimental example according to embodiments of the present invention.

In the present experimental example, when changing a temperature of the coating material by the laser LL while maintaining equally other conditions, the change in a viscosity of the coating material was measured, and results thereof are shown in FIG. 5.

Referring to FIG. 5, if the temperature of the coating material increased by about 5 degrees by the laser LL, it was found that the viscosity of the coating material decreased by 12 percent, and if the temperature of the coating material increased by about 10 degrees, the viscosity of the coating material decreased by 30 percent.

As previously explained, as the rotation speed of the substrate SB in the rotation direction RD increases, the thickness of the coating material RP at the edge of the substrate SB and close to the edge EP of the substrate supporter SP may become thicker relative to the thickness of the coating material RP closer to the center CP of the substrate SB. However, as shown in FIG. 6, by supplying the laser LL to areas where the thickness of the coating material RP is thicker, the viscosity of the coating material RP may be lowered, and the coating material RP may spread. It was found that the thickness of the coating material RP may be lowered even along the edge of the substrate SB, which has a thicker coating material RP relative to the thickness of the coating material RP closer to the center CP of the substrate SB.

In this way, according to embodiments of the present invention, by irradiating the laser LL to the coating material on the substrate SB and reducing the speed of the laser supply unit LG or increasing the intensity of the laser LL toward the edge of the substrate SB, the energy of the laser LL may be increased. Therefore, it is possible to prevent the coating material from being thicker at the edge of the substrate SB and form a thin and uniform coating material even along the edge of the substrate SB.

Next, another experimental example according to embodiments of the present invention is described. In the present experimental example, other conditions remain the same, after supplying a 10 ml coating material on a substrate SB, the substrate SB was rotated at 200 RPM, and the diffusion area of the coating material was observed in a first case without a laser supply and a second case with a laser supply.

When compared to the first case without the laser supply, the diffusion area of the coating material in the second case with the laser supply was wider. For example, when comparing the diameter of the diffusion area of the coating material, the diameter of the diffusion area of the coating material in the second case was about 1.11 times the diameter of the diffusion area of the coating material in the first case.

In this way, according to embodiments of the present invention, a thin and uniform thickness of the coating material may be provided on the substrate SB.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims. The above-disclosed subject matter is to be considered illustrative, and not restrictive, and the appended claims are intended to cover all such modifications, enhancements, and other embodiments, which fall within the scope of the present inventive concept. Thus, to the maximum extent allowed by law, the scope is to be determined by the broadest permissible interpretation of the following claims and their equivalents, and shall not be restricted or limited by the foregoing detailed description.

What is claimed is:

1. A spin coating apparatus comprising:
a substrate supporter configured to support a substrate,
a substrate supporter driver configured to rotate the substrate supporter,
a laser supply unit positioned above the substrate supporter and configured to supply a laser, and
a laser driver configured to drive the laser supply unit,
wherein the laser supply unit is configured to move along a first direction, the first direction being horizontal relative to a surface of the substrate when supported on the substrate supporter.

2. The spin coating apparatus of claim 1, wherein:
the laser supply unit is configured to move along the first direction at different speeds depending on positions relative to the substrate.

3. The spin coating apparatus of claim 2, wherein:
the substrate comprises a first region adjacent to a center of the substrate, a second region spaced apart from the first region toward an edge of the substrate along the first direction, and a third region adjacent to the edge of the substrate,
a first moving speed of the laser supply unit at a position corresponding to the first region of the substrate is greater than a second moving speed of the laser supply unit at a position corresponding to the second region of the substrate.

4. The spin coating apparatus of claim 3, wherein:
a second moving speed of the laser supply unit at the position corresponding to the second region of the substrate is greater than a third moving speed of the laser supply unit at a position corresponding to the third region of the substrate.

5. The spin coating apparatus of claim 4, wherein:
the laser supplied from the laser supply unit has a constant intensity.

6. The spin coating apparatus of claim 4, wherein:
an intensity of the laser supplied from the laser supply unit varies depending on the position of the laser supply unit relative to the substrate.

7. The spin coating apparatus of claim 6, wherein:
the intensity of the laser supplied at the position corresponding to the second region of the substrate is greater than the intensity of the laser supplied at the position corresponding to the first region of the substrate.

8. The spin coating apparatus of claim 7, wherein:
the intensity of the laser supplied at the position corresponding to the third region of the substrate is greater than the intensity of the laser supplied at the position corresponding to the second region of the substrate.

9. The spin coating apparatus of claim 2, wherein:
the laser supplied from the laser supply unit has a constant intensity.

10. The spin coating apparatus of claim 2, wherein:
an intensity of the laser supplied from the laser supply unit varies depending on the position of the laser supply unit relative to the substrate.

11. The spin coating apparatus of claim 1, wherein:
an intensity of the laser supplied from the laser supply unit varies depending on a position of the laser supply unit relative to the substrate.

12. The spin coating apparatus of claim 11, wherein:
the substrate comprises a first region adjacent to a center of the substrate, a second region spaced apart from the first region toward an edge of the substrate along the first direction, and a third region adjacent to the edge of the substrate,
the intensity of the laser supplied at a position corresponding to the second region of the substrate is greater than the intensity of the laser supplied at a position corresponding to the first region of the substrate.

13. The spin coating apparatus of claim 12, wherein:
the intensity of the laser supplied at the position corresponding to the third region of the substrate is greater than the intensity of the laser supplied at the position corresponding to the second region of the substrate.

14. The spin coating apparatus of claim 1, wherein:
the substrate comprises a first region adjacent to a center of the substrate, a second region spaced apart from the first region toward an edge of the substrate along the first direction, and a third region adjacent to the edge of the substrate,
the intensity of the laser supplied at a position corresponding to the second region of the substrate is greater than the intensity of the laser supplied at a position corresponding to the first region of the substrate.

15. The spin coating apparatus of claim 14, wherein:
the intensity of the laser supplied at the position corresponding to the third region of the substrate is greater than the intensity of the laser supplied at the position corresponding to the second region of the substrate.

16. The spin coating apparatus of claim 1, further comprising:
a main driver configured to control the substrate supporter driver and the laser driver.

17. The spin coating apparatus of claim 16, wherein:
the main driver is configured to transmit and receive a first signal with the substrate support driver, and configured to transmit and receive a second signal with the laser driver.

18. The spin coating apparatus of claim 16, wherein:
the laser supply unit is configured to move along the first direction at different speeds depending on positions relative to the substrate by the main driver, and
the laser supplied from the laser supply unit has a constant intensity.

19. The spin coating apparatus of claim 16, wherein:
the laser supply unit is configured to move along the first direction at different speeds depending on positions relative to the substrate by the main driver, and
an intensity of the laser supplied from the laser supply unit varies depending on the position of the laser supply unit relative to the substrate.

20. The spin coating apparatus of claim 16, wherein:
the substrate comprises a first region adjacent to a center of the substrate, a second region spaced apart from the first region toward an edge of the substrate along the first direction, and a third region adjacent to the edge of the substrate,
the main driver configured to control the substrate supporter driver and the laser driver such that the intensity of the laser supplied at a position corresponding to the second region of the substrate is greater than the intensity of the laser supplied at a position corresponding to the first region of the substrate and the intensity of the laser supplied at the position corresponding to the third region of the substrate is greater than the intensity of the laser supplied at the position corresponding to the second region of the substrate.
